(19) United States
(12) Patent Application Publication
(10) Pub. No.: US 2010/0044808 A1
(43) Pub. Date: Feb. 25, 2010

(54) METHOD OF MANUFACTURING A MEMS ELEMENT

(75) Inventors: Ronald Dekker, Eindhoven (NL); Geert Langereis, Eindhoven (NL); Hauke Pohlmann, Hamburg (DE); Martin Duemling, Hamburg (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/993,474

(22) PCT Filed: Jun. 27, 2006
(86) PCT No.: PCT/IB2006/052109

§ 371 Date: Dec. 21, 2007

(30) Foreign Application Priority Data
Jun. 30, 2005 (EP) 05105869.1

(51) Int. Cl. H01L 29/84; H01L 21/30

(52) U.S. Cl. 257/415; 438/50; 257/E29.324; 257/E21.211

(57) ABSTRACT

The device (100) comprises a substrate (10) of a semiconductor material with a first and an opposite second surface (1,2) and a microelectromechanical (MEMS) element (50) which is provided with a fixed and a movable electrode (52, 51) that is present in a cavity (30). One of the electrodes (51,52) is defined in the substrate (10). The movable electrode (51) is movable towards and from the fixed electrode (52) between a first gapped position and a second position. The cavity (30) is opened through holes (18) in the substrate (10) that are exposed on the second surface (2) of the substrate (10). The cavity (30) has a height that is defined by at least one post (15) in the substrate (10), which laterally substantially surrounds the cavity (15).

The invention relates to a method of manufacturing an electronic device that comprises a microelectromechanical (MEMS) element having a fixed electrode and a movable electrode, that are mutually separated by a gap in an opened position, which movable electrode is movable towards and from the fixed electrode, said method comprising the steps of:
providing at least one etching hole in the substrate from a second side that is opposite to the first side so as to expose an area of a sacrificial layer, and
removing the sacrificial layer with an etchant to the extent that the sacrificial layer is exposed to the etchant through the at least one etching hole in the substrate, therewith releasing the movable electrode from the fixed electrode.

The invention also relates to an electronic device that can be manufactured with the method.

Such a method and such a device are known from WO-A 2004/071943. The processing substrate in the known device comprises a bottom and a top semiconductor layer with an intermediate buried oxide layer. The buried oxide layer is therein the sacrificial layer, while the movable and the fixed electrode are present in the bottom semiconductor layer and extend perpendicular to the substrate surface. Parts of this buried oxide layer are kept. Contact plugs in the buried oxides provide an electrical connection to the fixed electrodes. The handling substrate is suitably removed after that the sacrificial layer is removed. Suitably, an additional substrate is bonded to the bottom semiconductor layer as a capping layer. Only the fixed electrodes will be bonded as the bottom semiconductor layer has been slightly thinned in the areas of the movable electrodes before removal of the sacrificial layer.

It is a disadvantage of the known device and the known method, that the removal of the sacrificial layer is difficult to control. The removal involves underetching, and the shape of the underetch can only be determined by the etching time.

It is therefore an object of the invention to provide a method of the kind mentioned in the opening paragraph, in which the removal of the sacrificial layer can be removed in a reliable manner.

This object is achieved in that prior to the provision of the etching holes from the second side it comprises the steps of:
providing a sacrificial layer in a first surface of a substrate, which sacrificial layer is provided by locally oxidizing the substrate and is laterally at least substantially surrounded by at least one post of the substrate; and
providing an electrode structure with a first of the electrodes, which electrode structure extends to at least one post of the substrate and is provided with a contact;

Then, the removal of the sacrificial layer results in the creation of the gap between the fixed and the movable electrode.

In the method of the invention, the sacrificial layer and at least one of the electrodes are present on the substrate. This allows to cover the sacrificial layer with an etch stop layer, so that the sacrificial layer can be selectively etched without giving rise to underetching problems. The etch stop layer may be a separate layer, but alternatively the—movable—electrode can be used as etch stop layer itself. The sacrificial layer is herein provided by oxidizing the substrate. Suitably, the technique known as shallow trench isolation is used thereto.

Moreover, the use of shallow trench isolation for the definition of the sacrificial layer allows an accurate definition of the material to be removed and thus the cavity to be created. This shallow trench isolation is applied during processing at the first side, e.g. the front-end processing. As a result, it may well be applied with a high resolution in the submicron scale, even down to advanced lithography dimensions in the order of 75 nm. Also, the posts of the substrate comprise another material than the sacrificial layer, and the sacrificial layer can be selectively etched with respect to the substrate. Additionally, the high resolution of the trench isolation and particularly the substrate posts allows to tune the mechanical properties of the posts. Particularly, they may be flexible or have a spring-like character.

An apparently related method is known from WO-A 00/009440. In this prior art method use is made of a substrate with a highly doped (n⁺) and a lowly doped (n⁻) substrate layer. Holes are etched from the first side through the highly doped (n⁺)-layer. After completion of the processing at the first side of the substrate, the lowly doped (n⁻)-layer is partially etched away, while using the interface between n⁺ and n⁻ layer as etch stop. This method has the disadvantage that the etching of the holes need to be combined with other front side etching. This is highly unpractical if also other elements need to be provided on the first side of the substrate: the holes are easily filled with any fluid, that cannot be removed properly due to capillary action. Moreover, this prior art method does not lead to a structure wherein the membrane is supported by the posts in the substrate.

Advantageously, the first electrode is defined in a layer of metal or polysilicon that may also be used for definition of a gate electrode of a transistor adjacent to the MEMS element. The gate dielectric is herein the sacrificial layer. When combined with transistors, the first electrode suitably extends laterally, e.g. parallel to the substrate surface. This is however not strictly necessary. In one embodiment, the first electrode is the fixed electrode, in another embodiment it is the movable electrode.

Use of a polysilicon gate as a movable electrode of a MEMS element is known per se, and for instance discussed in R. Maboudian and R. T. Howe, J. Vac. Sci. Techn. B 15 (1997), 1-20. However, the article relates only to etching from the top side and not to etching from the bottom side, e.g. through the substrate. Moreover, etching from the bottom side may reduce problems with capillary action. This problem is discussed in the article and essentially means that etchant tends to stay behind after removal of the sacrificial layer as a consequence of capillary forces. With the invention, access to the gap created in the removal of the sacrificial layer can be improved. Not only may the substrate be thinned sufficiently to have a short path to the gap, but also the number of etching holes may be enlarged, and their diameter may be larger. Furthermore, use can be made of processing separate from the conventional semiconductor manufacturing, which allows a greater variety of methods to be employed so as to overcome the capillary forces.

An additional and even more important advantage of the method of the invention, in comparison to the conventional release of a polycrystalline silicon movable electrode, is that this can be done after completion of the processing of layers on the processing substrate. This is problematic in the prior art, as the etching hole is a hole and any layer deposited thereon may enter the hole and contaminate the structure. It has often been proposed to provide a cap, but this tends to be an operation that must be carried out for each MEMS element individually, leading to substantial cost. Also bonding of a complete substrate has been proposed, but this also needs to be done with care. And it is all but easy, particularly not if a vacuum-tight encapsulation is desired, as is explained in EP-A 1,396,470. In the invention, the closure of the gap is the last step in the processing. This can be combined with a packaging approach if so desired.

In a first embodiment, a second sacrificial layer is provided on top of the first electrode, which second sacrificial layer is removed in the removal step, so that the first electrode is the movable electrode. The second sacrificial layer preferably also extends laterally to the movable electrode. Trenches may be present in the movable electrode both for optimization of mechanical behavior and for improved spreading of the etchant. Herewith, polycrystalline silicon or metal can be used as the movable electrode, instead of a conductive substrate region. Use of a polycrystalline movable electrode is known in the field of MEMS, in view of its good mechanical properties. Since the layer is deposited, its composition, thickness and shape may well be optimized for adequate bending. Alternatively, use can be made of a movable element, of which the movable electrode is part and which further comprises a thin film piezoelectric actuator so as to result in bending of the movable element.

Suitably, the electrodes of the MEMS element are oriented substantially parallel to the substrate (‘horizontal version’), although a ‘vertical’ version of the MEMS element could be designed alternatively. In the horizontal version, the fixed electrode may be defined either in a portion of the substrate or in an electrically conducting layer at the opposite side of the movable electrode. The definition of the fixed electrode in the substrate can be made in a robust manner. It has however the disadvantage that for RF properties the electrical conductivity of the substrate may be insufficient. Definition of the fixed electrode in a metal layer does not have this drawback. Furthermore, the fixed electrode may be provided in a layer with a substantial thickness. This layer can then be used for the definition of interconnects and inductors so as to limit electrical losses and so as to have a sufficiently high Q-factor, both of which are desired for RF applications.

In a most suitable modification hereof, the at least one etching hole in the processing substrate is sealed by application of a sealing material. Such a sealing material is suitably a material applied by chemical vapor deposition (CVD) and is for instance a oxide or nitride applied by phase enhanced CVD or a phosphosilicate glass, nitride or polysilicon applied by low pressure CVD. This technique of sealing is known per se from C. Liu & Y. Tai, IEEE Journal of Microelectromechanical Systems, 8 (1999), 135-145, that is incorporated herein by reference.

In another modification, the fixed electrode is defined in the substrate, for which object the substrate is sufficiently electrically conducting in a region adjacent to the gap, and material at the opposite side of the movable electrode is removed so as to expose the movable electrode. With this modification, the MEMS element is suitable for use as a sensor and particularly a pressure sensor. Even more preferably, the MEMS element is used as a microphone. Thereto, the movable electrode is embodied as a membrane, and the fixed electrode is provided with etching holes that are designed so as to function as acoustic holes. Suitably, the membrane is suspended by spring-like structures, as are known per se from the field of RF MEMS, particularly from U.S. Pat. No. 6,557,413B2. Such a suspended membrane can be tuned freely with respect to its compliance, and as such has a better acoustical performance if the membrane has an inherent larger stress of for instance at least 10 Mpa for a square membrane of 0.5 to 0.5 mm. Additionally, it does not have a bending profile with results in a more uniform transmission of an acoustical signal. However, a disadvantage is the acoustical short-cut due to the slits and a more fragile construction.

Most suitably, particularly in combination with this embodiment, a handling substrate is adhered to the substrate before provision of the etching hole in the processing substrate, therewith covering the electrode structure, and wherein the handling substrate is removed in an area overlying the movable electrode, so as to expose the movable electrode. Herewith, the device is given the desired strength.

In another embodiment, the substrate is sufficiently thinned and sufficiently doped to act as the movable electrode, and the first electrode is the fixed electrode. This embodiment is particularly advantageous in combination therewith that the electrode structure comprises an etch stop layer that covers the sacrificial layer and a further electrode that is present adjacent to the first electrode. In other words, use of an etch stop layer in combination with the fixed electrode in a metal layer allows that the fixed electrode can be smaller and that one or more further electrodes can be defined adjacent to the fixed electrode, while still, at least partially, overlying the movable electrode. This definition of further structures is also enabled, in that the metal layer is defined on the first side of the substrate. On this side, contrarily to the second side, lithography on a submicron scale resolution is well-known, and is even customarily applied for the definition of transistors. Thus the fixed electrode can in this manner be patterned with a much higher resolution than the movable electrode.

In a further modification hereof, the sacrificial layer is selectively etched to form a cavity therein at an area of the first electrode. This etching is carried out prior to deposition of the electrode structure. It is carried out such that the gap between the first electrode and the movable electrode will be smaller than the gap between the further actuation electrode and the movable electrode. In this manner the first—tuning—electrode is nearer to the movable electrode than the actuation electrode. A two-gapped design is known per se for MEMS tunable capacitors and aims at preventing of the pull-in effect, according to which the movable electrode drops down on the fixed electrode above a certain pull-in voltage. Generally, this two-gapped design is embodied in that the movable element is given a three-dimensional shape, while the fixed electrode is flat. In the present embodiment, the inverse situation is provided, and this with a gentle etching step so as to create a cavity. This inverse structure has the advantage that it can be manufactured more easily, particularly as the movable element may be kept as simple as possible. Additionally, the mechanical behavior is expected to improve, as the bending of the movable element is not limited to a certain area of the movable element. This tends to be the case in the prior art, where the area of the tuning electrode is not available for bending. Additionally, it is quite easy in the method of the invention to extend the two-gapped design to a three-gapped design or another design so as to prevent any pull-in, while at the same time reducing the actuation voltage and/or reducing sticking of the fixed electrode to the movable electrode.

The invention also relates to an electronic device provided with a substrate and a MEMS element of the above mentioned kind. Herein, the movable element comprises a movable electrode, that is movable towards and from the fixed electrode between a first gapped position and a second position, and that is substantially present in a space to be movable. Many examples of such electronic devices with MEMS elements are known.

A first type of MEMS elements comprises those embodied in cavities in the substrate or as part of a substrate. This type of MEMS elements is applied for sensors, for instance as acceleration sensors. Suitably, they are combined on one substrate with active circuitry used for detection of any signal provided by the sensor. Such devices have the disadvantage that the sensor must be made after completion of the processing of the active circuitry. Not only does this lead to additional process steps, but also a risk of failure is present in such sensor manufacturing, which includes quite some etching in and/or of cavities.

A second type of MEMS devices comprises those that are present on a substrate surface and specifically intended for RF applications. These are generally not integrated in integrated circuits of transistors, in view of the need of a high substrate resistance for definition of inductors. However, this lack of integration is again their drawback, as it implies that one needs a specific process for one specific MEMS application. It would be desired to have a process that can, with some minor amendments, be used for different application. Another drawback of this second type of MEMS is that for the actuation separate driver transistors are needed. Separate assembly of these is not cost-effective and may give rise to relative high losses in view of the relatively long path present between such driver transistors and the actual MEMS element.

It is therefore an object of the invention to provide an improved electronic device of the kind mentioned above which can be applied for different applications and may further be integrated in different processes.

This object is achieved in that part of the space around the movable element is defined as a shallow trench in the first surface of the substrate, which trench is laterally surrounded by at least one post of the substrate, and an etching hole is present from the second surface of the substrate to said part of the space. This device includes a space that has been defined by processing from the first surface, and is made after completion of the processing on the first side. At least part of the electrodes is also present on the first surface. The most important steps are thus set during processing on the first surface and may be included in the processing of the active circuitry. However, no etching of a cavity or space is needed during processing on the first surface of the substrate, and hence no cavity needs to be closed off again before processing can be continued.

In a first embodiment, said part of the space forms a gap between the fixed electrode and the movable element, and wherein one of the fixed electrode and the movable element is defined in a substrate portion adjacent to the second surface of the substrate and the other is defined in an electrically conductive layer on the first surface of the substrate. The MEMS device of this embodiment has its electrodes substantially parallel to the substrate. This is advantageous for integration, and also tends to reduce problems with removal of etchant, as the space is not very high.

In a specific modification hereof, the movable element is defined in the electrically conductive layer on the first surface of the substrate and is defined as a membrane that is able to resonate, and wherein the space extends on the other side of the movable element that faces away from the substrate.

More specifically, the space on the other side of the movable element extends such that the membrane is exposed, therewith enabling use of the MEMS element as a pressure sensor.

Most preferably, the MEMS element is a microphone, and the at least one etching hole in the substrate is defined as acoustic holes in the fixed electrode. It has been found that a preferred perforation fraction is in the range of 20 to 40% of the surface area, more specifically about 25 to 30% of the surface area. This is an optimum between low acoustic resistance (which is proportional to the bandwidth) and a large electrical capacitance (which is proportional to the signal strength). The acoustic holes preferably have a size up to about 30 microns and may have any shape. Preferred shapes are square and round. Small holes, with a diameter of 10 microns or less are preferred, because this results in a lower acoustic resistance for a given perforation fraction. Furthermore a thin substrate is preferred, as the depth of the holes increases the acoustic resistance and thus reduces bandwidth. The thickness of the substrate is in particular or the same order as the diameter of the acoustic holes or less.

In a second embodiment, the movable element and the fixed electrode are defined on the first surface of the substrate and the at least one etching hole is sealed with a sealing material so as to seal the space around the movable element. In this embodiment, packaging is integrated. Suitably, contact holes are present in the substrate adjacent to the etching holes, and contact pads for external coupling are exposed through these contact holes. The contact pads are suitably defined in a metal or polysilicon layer on the first surface of the substrate.

Suitably, a transistor is defined in or on the semiconductor substrate layer adjacent to the MEMS element, such that the first electrode of the MEMS element is defined in a same layer as a gate of the transistor. This exploits the inherent features of the device of the invention in a beneficial manner.

Preferably, a handling substrate is present, so as to cover any structures on the first surface during any thinning and the etching from the second surface of the substrate.

These and other aspects of the method and the device of the invention will be further explained with reference to the Figures, which are not drawn to scale and in which like reference numerals in different Figures refer to the same or corresponding parts, in which Figures:

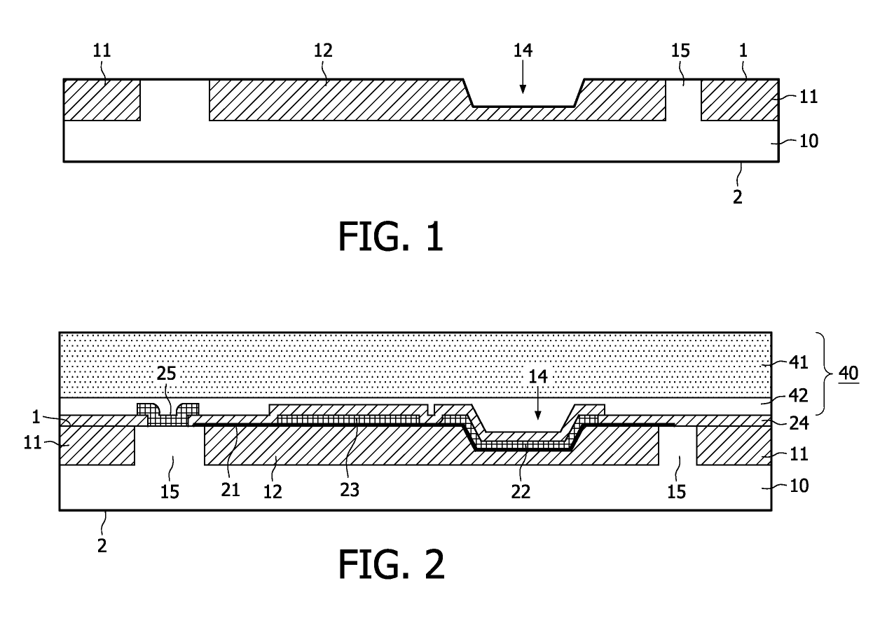

FIGS. 1-4 show in diagrammatical cross-sectional view a first embodiment of the method of the invention;

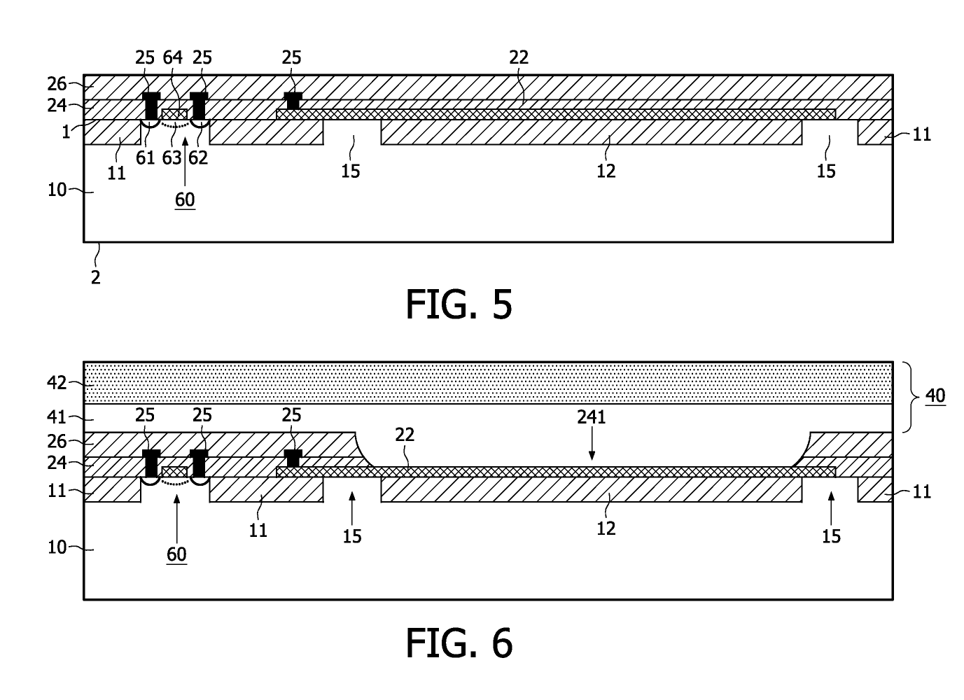

FIGS. 5-8 show in diagrammatical cross-sectional view a second embodiment of the method and the device of the invention;

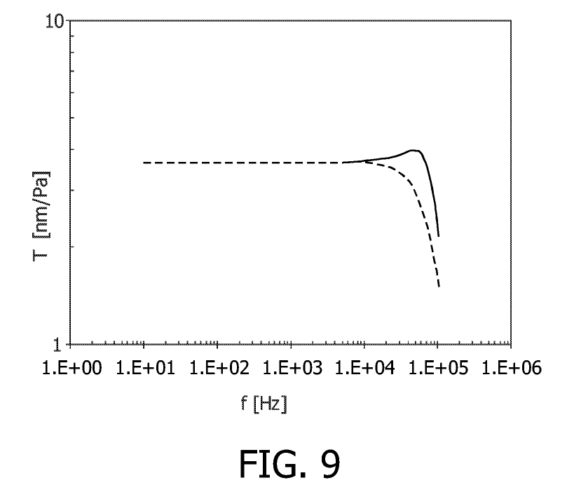

FIG. 9 shows a graph of the transduction in a microphone-embodiment of the device of the invention as made according to the FIGS. 5-8.

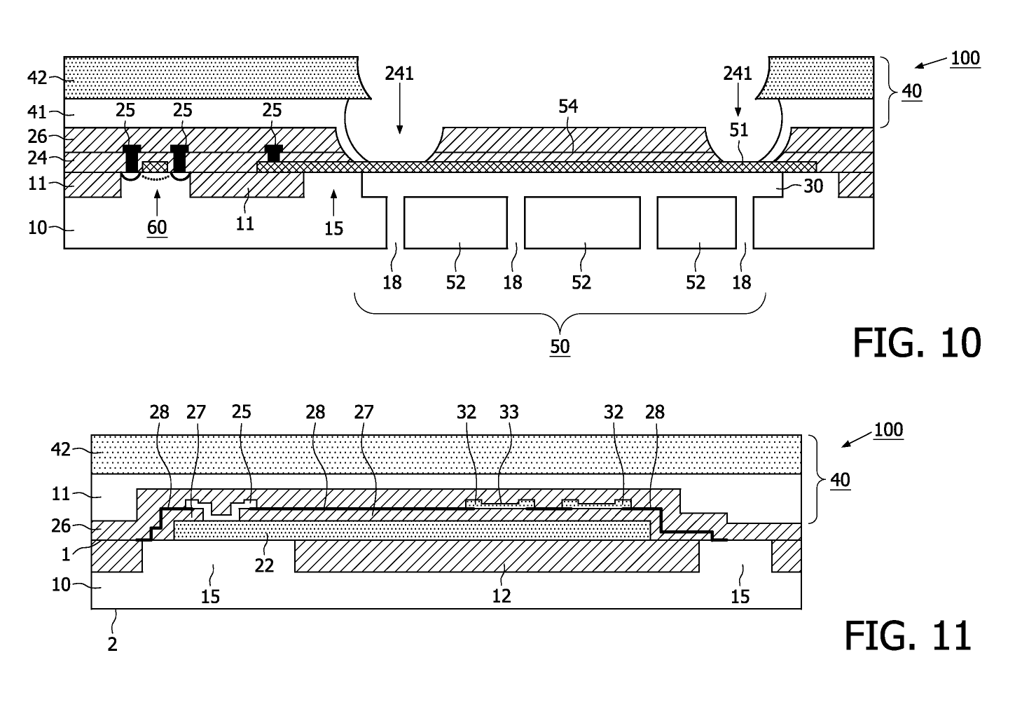

FIG. 10 shows a modification of the second embodiment, and

FIGS. 11-13 illustrate a further sealing step in the method of the invention.

FIGS. 1-4 show in diagrammatical cross-sectional view a first embodiment of the method of the invention.

FIG. 1 shows the substrate 10 with a first surface 1 and a second surface 2. The substrate 10 is in this case a silicon substrate, that is doped as n-type or p-type so as to be sufficiently conducting. The doping extends in particular to a depth of 10-20 microns. At the first surface 1 the substrate 10 has been locally oxidized, and therewith are created at least one post 15, a sacrificial layer 12 and further parts of the oxide layer 11. This oxidation is carried out with a process known as shallow trench oxidation, as explained in S. M. Sze, Semiconductor Physics and Technology, in this example, a MEMS element is created provided with a first and a second gap, as will be shown in further Figures. In order to achieve this, the sacrificial layer 12 is again structured to create a recess 14. Although not shown here, the substrate 10 may further contain any other elements, particularly transistors and diodes.

FIG. 2 shows the substrate 10 after a couple of further steps that are carried out on the first surface 1 of the substrate. An etch stop layer 21, in this example of silicon nitride and deposited by low-pressure chemical vapor deposition (LPCVD) is deposited on the sacrificial layer 12, extending to the post 15. Metal patterns 22, 23 are deposited hereon, suitably in aluminum or an aluminum alloy. Both patterns 22, 23 will function as a movable electrode in the final MEMS element. The pattern 22 extends into the recess 14 and has a tuning function. The pattern 23 extends on the sacrificial layer 12 only and has a actuation function. The metal patterns 22, 23 are suitably coupled to contacts or other elements through interconnects that are not shown. A dielectric layer 24 is applied on top of the metal patterns, and suitably comprises an oxide, a nitride or an organic dielectric layer, such as benzocyclobutane (BCB). A contact 25 extends through the dielectric layer to the substrate 10. This contact 25 allows to contact the movable electrode that will be defined in the substrate 10.

The substrate 10 with its deposited layers is covered with an encapsulation 40. This is in this case a glass substrate 41 that is attached the dielectric layer 24 and the contact 25 with an adhesive 42. Alternatively, a ceramic substrate or a second semiconductor substrate may be applied instead of the glass substrate. Furthermore, a resin layer may be applied, such as for instance a polyimide or an epoxy overmould. It is also possible that a metal layer of sufficient thickness is applied, either by growth—electroplating or electroless nickel or by assembly. Combinations are possible as well. For instance, a temporary handling substrate may be attached to the resin layer and be removed after processing on the second surface 2 of the substrate 10.

Although not shown, contact pads are integrated in the device. Such contact pads may be defined either to the first surface 1 of the substrate 10, similar to the contact 25. These contact pads are then exposed by locally removing the substrate. Most suitably, such contact pads are provided on top of a oxide island, that is laterally surrounded by posts of silicon. When in a further step the oxide is selectively removed, these contact pads may be exposed. Alternatively, contact pads may be provided adjacent to the encapsulation. They may be exposed after the processing on the second surface 2 of the substrate 10. In this example of a glass substrate 41, exposure of the contact pads involves a process such as known per se from Shellcase. In the case of a removable handling substrate and a resin layer, a further metallization may be provided through the resin layer.

Although not shown here, passive elements such as striplines, resistors, inductors and capacitors may be integrated in the device by deposition and patterning of specific layers on the first surface 1 of the substrate 10. Then, the metallization will involve more layers than merely the patterns 22,23 shown here.

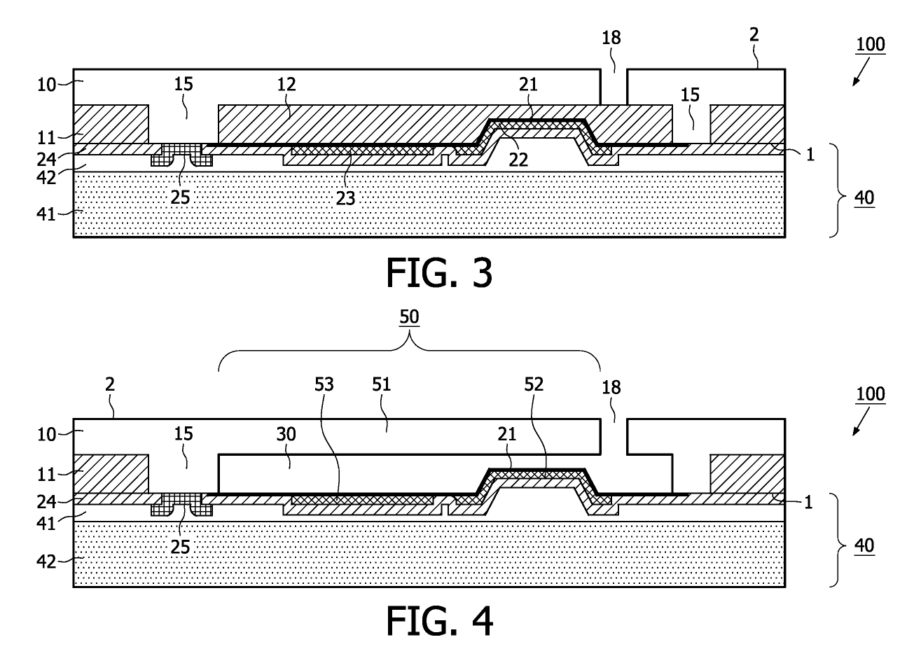

FIG. 3 shows the device 100 in a further stage of the processing, that is carried out at the second surface 2 of the substrate 10. The processing involves first of all thinning of the substrate by grinding and optionally a further wet-etching step. Subsequently, the substrate 10 is patterned to create holes 18. The sacrificial layer 12 is exposed through these holes 18.

FIG. 4 shows the resulting device 100 after removal of the sacrificial layer 12, wherein the cavity 30 is formed. Simultaneously, other parts of the oxide layer 11 are not removed, as these are not exposed to the etching solution. Use can be made of wet etching or plasma etching for the removal of the oxide layer. Now the MEMS element 50 is ready, and comprises the fixed electrode 52, 53 and the movable electrode 51 that is defined in the substrate 10.

Although not shown, a further packaging layer may be provided on this second surface 2 of the substrate 10. Such a packaging layer is suitably provided in an assembly step. One specifically suitable process is the use of a double photoresist layer, with apertures for the provision of solder balls. Such a photoresist layer is suitably provided as a sheet, in order to prevent filling of the cavity. This process is explained in U.S. Pat. No. 6,621,163. Another suitable process is the use of a bendable substrate, that is attached through anchoring structures, as is explained in WO-A 2003/084861. In a further suitable process, a ring-shaped contact pad is defined around the MEMS element 50 and provided with solder. When assembled on an opposed carrier, the ring-shaped solder allows a hermetic package. In order to provide a suitable electrical isolation between the solder and the substrate 10, the ring is suitable surrounded by a ring-shaped post of silicon and another ring of oxide material.

FIGS. 5-8 show in diagrammatical, cross-sectional view several stages of a second embodiment of the method of the invention. This embodiment leads to a device 100 that comprises a MEMS element 50 and active elements 60 that are interconnected to form a CMOS integrated circuit. The MEMS element 50 of this embodiment is designed to act as a microphone; however, its design could be optimized for another application such as a high-frequency resonator, a sensor, or a switch.

FIG. 5 shows the substrate 10 with its first surface 1 and second surface 2. The first surface 1 is locally oxidized so as to create the sacrificial layer 12, at least one post 15 and further parts 11 of the oxide layer. Additionally, doped regions 62, 63 are provided in the substrate to create one or more active elements 60. The doped regions function in this example as the source 61 and the drain 62 of a field effect transistor 60, and are mutually coupled through a channel 63. Conductive pattern 22 is provided on the sacrificial layer 12. A gate electrode 64 is provided in the same layer of conductive material as the conductive pattern. In this example, the conductive material is polysilicon that is suitably and sufficiently doped as known in the art. Other examples of suitable conductive materials include metals and silicides. One or more dielectric layers 24 and contacts 25, as well as not shown interconnects and contact pads are provided after provision of the transistor 60 in a manner known to the skilled person. A passivation layer 26 covers this structure of dielectric layers 24, contacts 25 and interconnects. The contact pads may be provided on the first surface 1 of the substrate 10, so that they are exposed by local removal of the substrate, as discussed in relation to the first embodiment. Alternatively or additionally, they may be provided below the passivation layer 26 and exposed through apertures therein. The contact pads may even be present on the passivation layer 26, so as to use the available surface area more adequately. This latter option is preferred for this embodiment, as will be discussed later on.

FIG. 6 shows the substrate 10 in a second stage of the process after patterning of the passivation layer 26 and provision of an encapsulation 40. The passivation layer 26 and the underlying dielectric layer 24 are patterned to expose the conductive pattern 22. This conductive pattern 22 will act as the movable electrode of the MEMS element 50. The early exposure of this pattern 22 allows that its lateral dimensions are well-defined. Therewith the size of the movable electrode 52 is set, which has consequences for the performance, in particular resonance frequencies. The patterning of layers 24,26 is suitably carried out with a wet-etching technique. This is allowed in that the conductive patterns 22 effectively acts as etch stop layer. Consequently, the diameter of the aperture 241 in the patterned layers 24,26 decreases towards the conductive pattern 22. Therewith, the conductive pattern 22, that will be released to act as a membrane in a later stage of the process, is anchored effectively. As a result, the mechanical stability is optimal.

In case that there are contact pads below the passivation layer 26, these are preferably exposed in the same patterning step. As the contact pads are made of conductive material, the contact pads themselves can be used as etch-stop, so that the aperture 241 above the conductive pattern 22 will be deeper than that above the contact pads.

The apertures 241 are subsequently filled with adhesive 42, and covered with a glass plate 41. Other forms of encapsulation 40 are possible, but the glass plate 41 appears very suitable in this case: the adhesive 41 may be used to overcome non-planarities; the glass plate 41 may be patterned with powder-blasting or other techniques known per se, better than an epoxy; and the glass plate provides sufficient mechanical rigidity, better than a flexible polyimide resin layer.

Moreover, in case that the conductive pattern 22 is not a plate-like, closed structure, but includes holes or slits, this encapsulation process still works adequately: then, the wet-etching process may extend through the holes or slits and even partially etch away the underlying sacrificial layer 12. This release of the conductive pattern 22 as a free-standing membrane could have a negative impact during the subsequent process step wherein the substrate 10 is thinned from its second surface 2. However, the adhesive 42 effectively fills the holes. And the adhesive 42 can be effectively removed in a further process step.

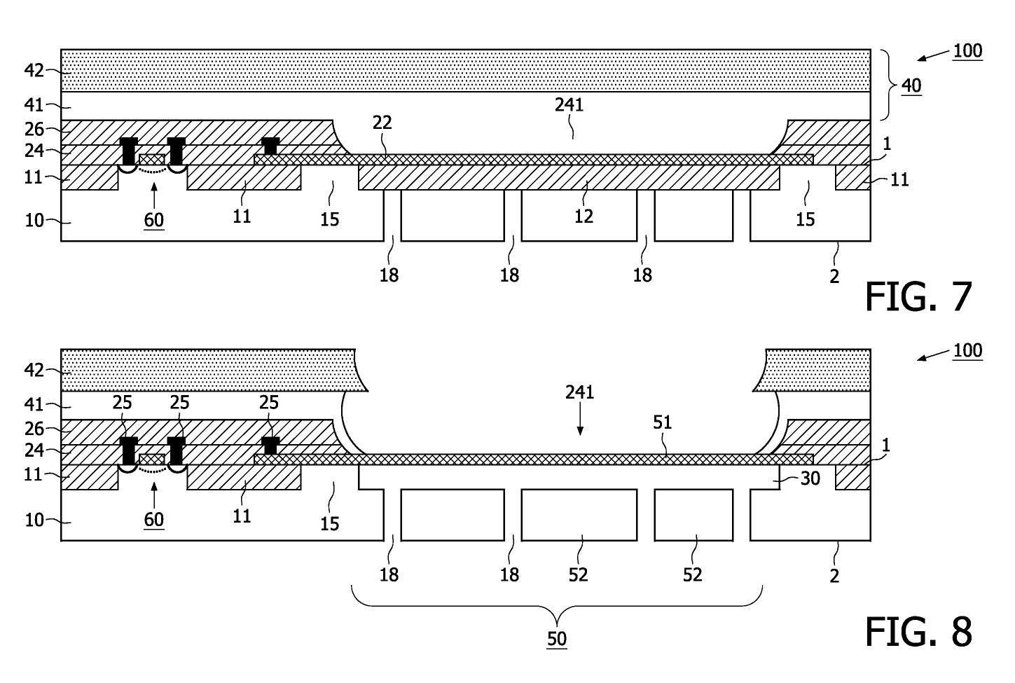

FIG. 7 shows the device 100 in a further stage of the process after processing of the substrate 10 from its second surface 2. This involves thinning of the substrate 10 by grinding and wet damage etch to a thickness in the order of 10-50 microns. Thereafter, holes 18 are provided into the substrate 10. This is most suitably carried out by dry etching. The sacrificial layer 12 will act as an etch stop layer for the dry etching process.

FIG. 8 shows the resulting device 100 after further removal steps. This includes patterning of the glass plate 41, wet-etching of the sacrificial layer 12 from the second side 2 and local removal of the adhesive 42 so as to release the conductive pattern 22 to form a membrane. The removal of the adhesive is suitably carried out in an oxygen plasma etch. Now the MEMS element 50 is ready; the membrane 22 acts herein as the movable electrode 51, and the substrate region as the fixed electrode 52. The movable electrode 51 fulfills the function of the diaphragma in a microphone, and the fixed electrode fulfils the function of backplate.

As the diaphragm is created by release of the polysilicon layer, the microphone performance is bound to the stress and thickness of this layer. For a diaphragm of 0.5×0.5 mm², a low tensile stress, particularly of less than 10 Mpa is preferred. If this would not be achievable, one may use a membrane suspended by beams. A suspended membrane can be tuned freely with respect to its compliance and does not have the disadvantage of a bending profile. However, the use of a suspended membrane has as a disadvantage that there is an acoustical short-cut due to the slits and the fragile construction.

Preferably, the diaphragm has a thickness of approximately 300 nm and a size of 0.5×0.5 mm². For polysilicon with a density of 2.33·10³ kg/m³ the mass is 1.75·10⁻¹⁰ kg for a suspended diaphragm and 2.52·10⁻¹⁰ kg effectively for the membrane as shown in the Figure.

The air gap in the present invention is fixed, and corresponds to the thickness of the sacrificial portion, i.e. oxide layer in the substrate. In this example, it is about 1 micrometer.

A measure for a proper microphone is the Q-factor related to a resonance frequency of the membrane. This Q-factor can be expressed in terms of the acoustical resistance of the air in the airgap Rₐ, the mass of the diaphragm L_{d} and the compliance of the diaphragm C_{d}. When the acoustical radiation mass, the mass of the air in the air gap and the compliance of the back chamber volume are neglected, the Q-factor can be approximated by

$$Q \approx \frac{1}{{R}_{a}} \sqrt{\frac{{L}_{d}}{{C}_{d}}} . \qquad ( 1 )$$

The quality factor Q is preferably large. When Q>1, the bandwidth of the microphone is close to the resonance frequency of the membrane. In that case, the spectrum shows an increase in sensitivity close to the resonance frequency. For Q<1 however, the bandwidth is determined by the acoustic resistance of the air gap and the compliance of the membrane.

It is therefore important to reduce the acoustical resistance Rₐ by making large holes and a large air gap. However, electrical sensitivity is reduced by larger holes and an increase in air gap (C=εA/d where size A is decreased due to the holes and distance d is the air gap distance).

The solution appears therefore the modification of the shape of the acoustic holes in the backplate. It was found that this may be suitably achieved in the use of a specific etching process, that is wet-chemical etching.

FIG. 9 shows a graph wherein the simulated frequency spectra are shown for two types of microphones: one with conical holes that have been made with wet-chemical etching, and one with straight acoustic holes, that have been prepared by dry etching. The output is given in mechanical quantities being the transduction from sound pressure to membrane movement. Transduction to the electrical domain is frequency independent. In the chosen hole geometry, the dry-etched microphone does not have the full bandwidth due to the resistance of the air in the holes.

For a 0.5×0.5 mm² diaphragm, square acoustic holes in the substrate of 5×5 μm² with a density of etching holes 18 of 10⁸ per m² (25% of the backplate is perforated) appears to be a typically suitable configuration. The acoustical resistance Rₐ consists of an “orifice” part which is the result of the air pushed out of the air gap and a tube part which is the result of the thickness of the backplate, i.e. the fixed electrode 52 as defined in the substrate. When the holes are etched anisotropically using reactive ion etching, the acoustic tube resistance determines 40% of the total acoustical resistance (for the above sketched configuration). We can remove this component by using wet-chemical etching of the acoustic holes, as is clear from FIG. 9.

FIG. 10 shows a further modification of this second embodiment. Herein, the passivation layer 26 and the dielectric layer 24 are patterned so as to expose the conductive pattern 22 only locally. Particularly, the exposed area 241 is ring-shaped or similar. This results in the creation of a mass 54 on top of the movable electrode 51. Although not shown here, the mass 54 may include several metal layers to increase its weight. Alternatively, a relatively large mass may be applied in the from of a disk of glass from the supporting glass substrate. The resulting MEMS element 50 may be suitably applied as a sensor for measuring accelerations.

In an additional step, the holes 18 in the second surface 2 of the substrate 10 may be closed by application of a sealing layer 19. Such a sealing layer 19 may be applied in phase-enhanced chemical vapor deposition at reduced pressure, as known per se from Chang Liu and Yu-Chong Tai, IEEE Journal of Microelectromechanical Systems, 8 (1999), 135-145. The sealing layer 19 comprises for instance an oxide, but a nitride or another material is not excluded. As a consequence of the low pressure, the oxidation occurs selectively at the outside of the holes 18. The resulting layer is then constituted by caps that bridge and close off the holes. Suitably, the holes 18 have a width of less than 5 microns, and preferably in the range of 0.5-2.5 microns. It is not excluded that some of the holes are opened again, for instance for exposing the contact pads, or for opening the cavity 30. This is preferred when using the MEMS element in a microphone application.

This sealing step is illustrated with reference to FIG. 11-13. These Figures show in cross-sectional and diagrammatical view a third embodiment of the method of the invention.

FIG. 11 shows the substrate 10, with on its first surface 1 several layers and an encapsulation 40. The substrate 10 is shown here in the situation in which it has already been thinned from the second surface 2. The thinning of the substrate 10 is carried out to a thickness of less than 50 microns, preferably in the range of 20-30 microns, exclusive the thickness of the posts 15. As in the earlier embodiments, the substrate 10 is at its first surface 1 locally oxidized to form a sacrificial layer 12, posts 15 and further parts of the oxide layer 11. A conductive pattern 22 is applied on top of the sacrificial layer 12 and extends to the at least one post 15. A second sacrificial layer 27 is provided on top of the conductive pattern 22, for instance as a layer of tetra-ethyl-orthosilicate (TEOS). An etch stop layer 28 is provided hereon in a suitably patterned form. In this example, use is made of low pressure chemical vapour deposition (LPCVD) for the deposition of a nitride as etch stop layer 28. Contacts 25 and further patterns 32,33 are provided hereon. The material of these patterns 22, 25, 32, 33 is suitably polysilicon, but could be alternatively a metal such as copper or a copper or aluminum alloy, or even a conductive nitride or oxide, such as TiN or Indium Tin Oxide. It is moreover possible that the conductive pattern 22 is made of another material than the patterns 25, 32, 33. A suitable choice is for instance that the conductive pattern 22, that will act as movable electrode, is made of polysilicon, while the other patterns are made in TiN with optionally Al. Alternatively, the conductive pattern 22 is provided on a further layer, such as for instance a piezoelectric layer. A piezoelectric MEMS device will then result.

A passivation layer 26 is applied on top of the patterns 25, 32, 33. Suitably, but not shown, are further dielectric and metal layers provided for definition of interconnects, contact pads and any passive components such as couplers, striplines, capacitors, resistors and inductors. Moreover, the substrate 10 may include further elements such as transistors or trench capacitors. Suitably, the contact pads are in this example provided at the side of the substrate 10.

The encapsulation 40 comprises for instance a glass plate 41 and an adhesive layer, but may alternatively be made of an overmoulded resin layer, such as an epoxy or any other layer. The encapsulation 40 is needed for chemical protection and for the provision of sufficient stability; and any structure fulfilling these requirements can be used. Particularly, in this example, there is no need for patterning of the encapsulation or removal of the encapsulation 40

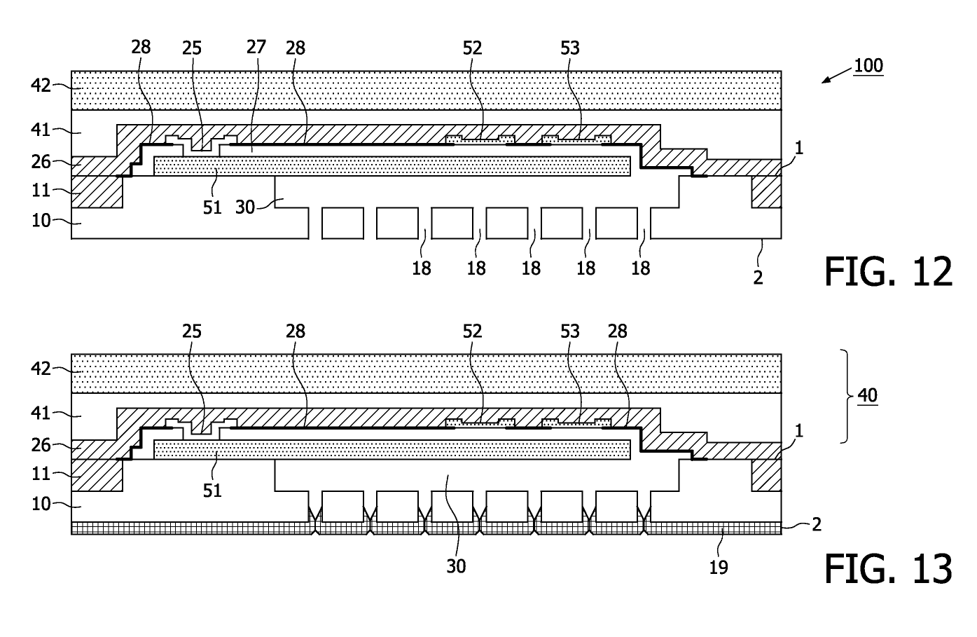

FIG. 12 shows the device 100 after that holes 18 are provided in the substrate 10 from its second surface 2, and the sacrificial layers 12, 27 have been removed. This removal is effectively carried out with wet-chemical etching. Advantageously, the conductive pattern 22 comprises holes or slits so as to provide an effective distribution of the etchant and reduce problems with capillary action. The removal may alternatively be carried out, at least partially with dry etching. This removal step releases the conductive pattern 22, that is used as the movable electrode 51 of the MEMS element 50. The conductive patterns 32, 33 are exposed as fixed electrodes 52, 53 of the MEMS element. Particularly, the electrode 52 is actuator electrode, and the electrode 53 is a sense electrode. Although not shown here, the region of the substrate around the holes 18 could be applied as a further fixed electrode. Evidently, the design of the movable electrode 51 is illustrative only. A doubly or multiply clamped movable electrode 51 could be applied alternatively, and spring structures may be incorporated in this movable electrode 51.

FIG. 13 shows the final device 100 with the sealing layer 19. In this example use is made of a PECVD oxide layer. Suitably, the thickness of the sealing layer 19 is of the same order as the width of the holes 18. Then, the cavity 30 will be closed automatically due to the poor step coverage of the PECVD oxide. The resulting pressure in the cavity 30 is equal or similar to the reduced pressure in the reactor used for the deposition of the PECVD oxide. This is for instance 400-800 mTorr.

### REFERENCE NUMERALS

1 first surface of substrate 10
2 second surface of substrate 10
10 substrate
11 oxide layer
12 sacrificial layer
14 recess
15 post
18 holes
19 sealing layer
21 etch stop layer
22, 23 conductive pattern
24 dielectric layer
25 contact
26 passivation layer
27 second sacrificial layer
28 etch stop layer
30 cavity
32,33 conductive patterns
40 encapsulation
41 glass plate
42 adhesive
50 MEMS element
51 movable electrode
52 fixed electrode
54 mass
60 active element, particularly transistor
61 doped region, particularly source electrode
62 doped region, particularly drain electrode
63 channel
64 gate electrode
100 final device
241 aperture

1. A method of manufacturing an electronic device that comprises a microelectromechanical (MEMS) element which is provided with a fixed electrode and a movable electrode, that is present is a cavity and is movable towards and from the fixed electrode between a first gapped position and a second position, said method comprising the steps of:
providing a sacrificial layer in a first surface of a substrate,
providing an electrode structure with a first of the electrodes on the sacrificial layer;
providing at least one etching hole in the substrate from a second surface that is opposite to the first surface, which etching hole extends so far as to expose an area of the sacrificial layer, and
removing the sacrificial layer with an etchant through the at least one etching hole in the substrate, therewith creating the cavity and a gap between the fixed and the movable electrode,
characterized in the sacrificial layer is provided by locally oxidizing the substrate and is laterally at least substantially surrounded by at least one post of the substrate, while said electrode structure extends to at least one post of the substrate and is provided with a contact.

2. A method as claimed in claim 1, wherein a second sacrificial layer is provided on top of the first electrode, which second sacrificial layer is removed in the removal step, so that the first electrode is the movable electrode.

3. A method as claimed in claim 2, wherein the fixed electrode is defined in a metal layer that is provided on top of the second sacrificial layer.

4. A method as claimed in claim 3, wherein the at least one etching hole in the processing substrate is sealed by application of a sealing material.

5. A method as claimed in claim 2, wherein the fixed electrode is defined in the substrate, for which object the substrate is sufficiently electrically conducting in a region adjacent to the gap.

6. A method as claimed in claim 5, wherein a handling substrate is adhered to the substrate before provision of the etching hole in the processing substrate, therewith covering the electrode structure, and wherein the handling substrate is removed in an area overlying the movable electrode, so as to expose the movable electrode.

7. A method as claimed in claim 1, wherein the substrate is sufficiently thinned and sufficiently doped to act as the movable electrode, and the first electrode is the fixed electrode.

8. A method as claimed in claim 7, wherein the electrode structure comprises an etch stop layer that covers the sacrificial layer and a further electrode that is present laterally to the first electrode.

9. A method as claimed in claim 8, wherein prior to deposition of the electrode structure the sacrificial layer is selectively etched to form a cavity therein at an area of the first electrode, such that the gap between the first electrode and the movable electrode will be smaller than the gap between the further actuation electrode and the movable electrode.

10. An electronic device comprising a substrate of a semiconductor material with a first and an opposite second surface and a microelectromechanical (MEMS) element which is provided with a fixed and a movable electrode that is present in a cavity and is movable towards and from the fixed electrode between a first gapped position and a second position, at least one of which electrodes is defined in the substrate, which cavity is opened through holes in the substrate that are exposed on the second surface of the substrate,
wherein the cavity has a height that is defined by at least one post in the substrate, which laterally substantially surrounds the cavity.

11. An electronic device as claimed in claim 10, wherein the movable electrode is defined in an electrically conductive layer on the first surface of the substrate, and is comprised in a membrane that is also exposed on a side remote from the cavity.

12. An electronic device as claimed in claim 10, wherein a transistor is defined in or on the semiconductor substrate layer adjacent to the MEMS element, such that the first electrode of the MEMS element is defined in a same layer as a gate of the transistor.

13. An electronic device comprising a substrate of a semiconductor material with a first and an opposite second surface and a microelectromechanical (MEMS) element which is provided with a fixed and a movable electrode and a cavity, which movable electrode is movable towards and from the fixed electrode between a first gapped position and a second position,
wherein the movable electrode is present on the substrate, in which a cavity is created below the movable electrode, which cavity is closed off by a part of the substrate provided with holes and a passivation layer closing the said holes.
